(19) United States
(12) Patent Application Publication
(10) Pub. No.: US 2014/0179106 A1
(43) Pub. Date: Jun. 26, 2014

(54) IN-SITU METAL RESIDUE CLEAN

(71) Applicant: LAM RESEARCH CORPORATION, Fremont, CA (US)

(72) Inventors: Qinghua ZHONG, Fremont, CA (US); Yifeng ZHOU, Fremont, CA (US); Ming-Shu KUO, San Ramon, CA (US); Armen KIRAKOSIAN, Walnut Creek, CA (US); Siyi LI, Fremont, CA (US); Srikanth RAGHAVAN, Fremont, CA (US); Ramkumar VINNAKOTA, Sunnyvale, CA (US); Yoshie KIMURA, Castro Valley, CA (US); Tae Won KIM, Dublin, CA (US); Gowri KAMARTHY, Pleasanton, CA (US)

(73) Assignee: Lam Research Corporation, Fremont, CA (US)

(21) Appl. No.: 13/725,848

(22) Filed: Dec. 21, 2012

(51) Int. Cl. H01L 21/306

(52) U.S. Cl. CPC H01L 21/306
USPC 438/689

(57) ABSTRACT

A method for forming devices in an oxide layer over a substrate, wherein a metal containing layer forms at least either an etch stop layer below the oxide layer or a patterned mask above the oxide layer, wherein a patterned organic mask is above the oxide layer is provided. The substrate is placed in a plasma processing chamber. The oxide layer is etched through the patterned organic mask, wherein metal residue from the metal containing layer forms metal residue on sidewalls of the oxide layer. The patterned organic mask is stripped. The metal residue is cleaned by the steps comprising providing a cleaning gas comprising BCl₃ and forming a plasma from the cleaning gas. The substrate is removed from the plasma processing chamber.

### BACKGROUND OF THE INVENTION

### Field of the Invention

The invention relates to a method of forming semiconductor devices on a semiconductor wafer. More specifically, the invention relates to selectively etching a dielectric layer with respect to an organic mask and a metal containing mask or etch stop.

In forming semiconductor devices, some devices may be formed by selectively etching an etch layer with respect to an organic mask and a metal containing mask or etch stop.

### SUMMARY OF THE INVENTION

To achieve the foregoing and in accordance with the purpose of the present invention, a method for forming devices in an oxide layer over a substrate, wherein a metal containing layer forms at least either an etch stop layer below the oxide layer or a patterned mask above the oxide layer, wherein a patterned organic mask is above the oxide layer is provided. The substrate is placed in a plasma processing chamber. The oxide layer is etched through the patterned organic mask, wherein metal residue from the metal containing layer forms metal residue on sidewalls of the oxide layer. The patterned organic mask is stripped. The metal residue is cleaned by the steps comprising providing a cleaning gas comprising BCl₃ and forming a plasma from the cleaning gas. The substrate is removed from the plasma processing chamber.

In another manifestation of the invention, a method for forming devices in an oxide layer over a substrate, wherein a metal containing layer forms at least either an etch stop layer below the oxide layer or a patterned mask above the oxide layer, wherein a patterned organic mask is above the oxide layer is provided. The substrate is placed in a plasma processing chamber. The oxide layer is etched through the patterned organic mask, wherein metal residue from the metal containing layer forms metal residue on sidewalls of the oxide layer. The patterned organic mask is stripped. The metal residue is cleaned by the steps comprising providing a cleaning gas comprising BCl₃ and Cl₂, wherein the cleaning gas has a flow ratio of BCl₃ to Cl₂ that is greater than 2:1 and forming a plasma from the cleaning gas, The substrate is removed from the plasma processing chamber.

These and other features of the present invention will be described in more details below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a flow chart of an embodiment of the invention.

FIGS. 2A-D are schematic cross-sectional views of a stack etch according to an embodiment of the invention.

FIG. 3 is a schematic view of a plasma processing chamber that may be used in an embodiment of the invention.

FIG. 4 is a schematic view of a computer system that may be used in practicing the invention.

FIGS. 5 A-B are schematic views of the plasma reactor during an embodiment of the invention.

FIG. 6 is a more detailed flow chart of a metal residue cleaning step.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

In the formation of some semiconductor devices, it is desirable to etch a dielectric layer, such as silicon oxide, with respect to an organic mask, such as a spin on material or amorphous carbon, and a metal containing hardmask, such as titanium nitride (TiN) or titanium (Ti). In other semiconductor processes, it is desirable to etch an etch layer disposed below a patterned organic mask with features, where a metal containing hardmask is formed on the bottoms of some of the organic mask features. A photoresist mask may be used to open a pattern in an organic layer to form an organic mask.

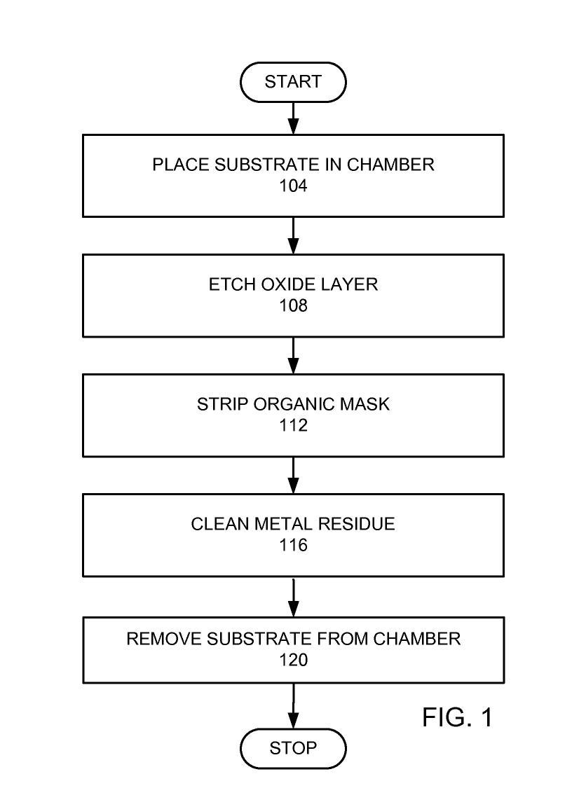

FIG. 1 is a high level flow chart of an embodiment of the invention. In this embodiment, a substrate with an oxide etch layer disposed under a patterned organic mask with features and a metal containing hardmask at the bottom of features of the patterned organic or a metal containing etch stop is placed in an etch chamber (step 104). The oxide etch layer is selectively etched with respect to the patterned organic mask and the metal containing hardmask or etch stop (step 108). The patterned organic mask is stripped (step 112). Metal residue is cleaned (step 116). The substrate is removed from the etch chamber (step 120).

### EXAMPLE

Etch Layer with Organic Mask, Metal Containing Hardmask, and Metal Containing Etch Stop

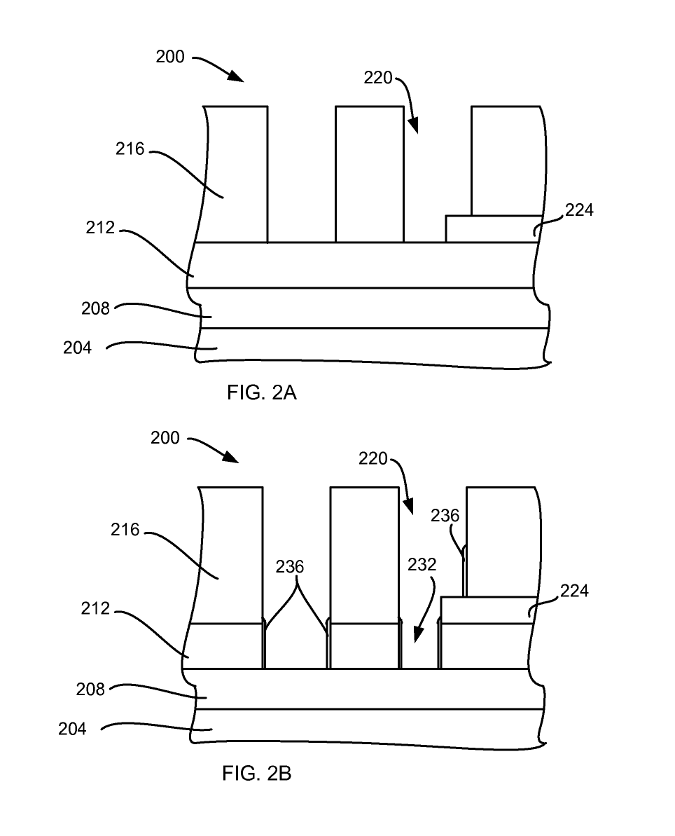

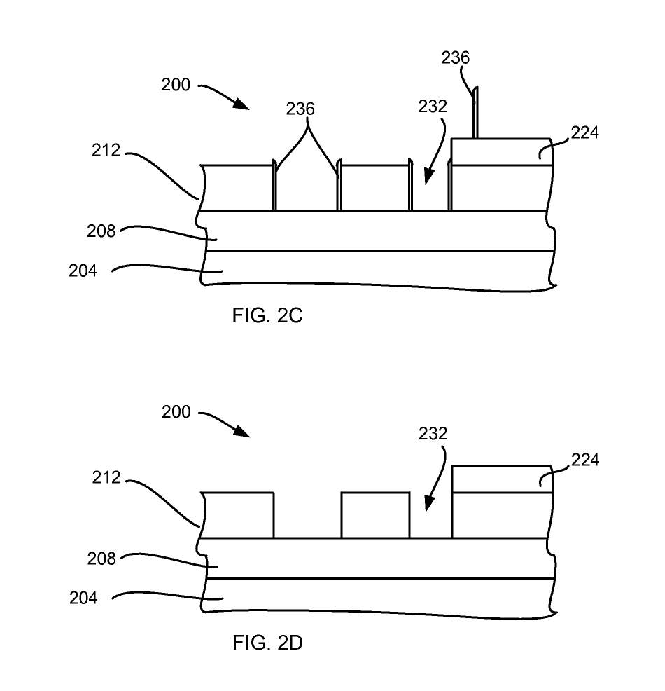

In an embodiment, a substrate with an oxide etch layer disposed under a patterned organic mask with features and a metal containing hardmask at the bottom of features of the patterned organic and a metal containing etch stop is placed in an etch chamber (step 104). FIG. 2A is a schematic cross-sectional view of a stack 200 with a substrate 204 with a metal containing etch stop layer 208 disposed below an oxide etch layer 212, disposed below an organic mask 216 with organic mask features 220. At the bottom of some of the organic mask features is a metal containing hardmask 224. In this example, one or more layers may be disposed between the substrate 204 and the etch stop layer 208, or between the etch stop layer 208 and the etch layer 212, or the etch layer 212 and the organic mask 216 or hardmask 224. In this example, the organic mask 216 is amorphous carbon, the hardmask 224 is titanium nitride (TiN), the metal containing etch stop 208 is also TiN, and the oxide etch layer 212 is silicon oxide (SiO).

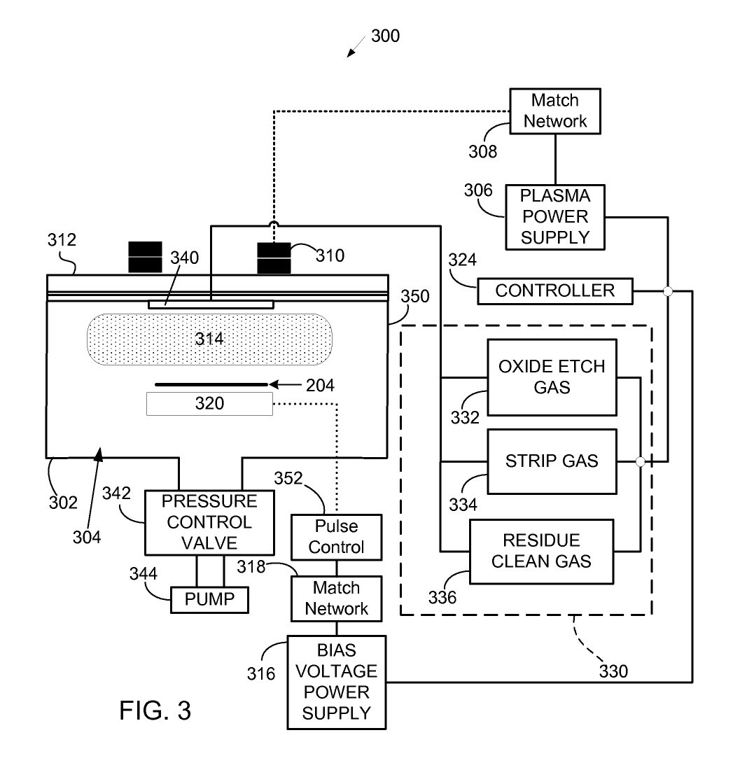

FIG. 3 schematically illustrates an example of a plasma processing system 300 which may be used in one embodiment of the present invention. The plasma processing system 300 includes a plasma reactor 302 having a plasma processing chamber 304 therein defined by a chamber wall 350. A plasma power supply 306, tuned by a match network 308, supplies power to a TCP coil 310 located near a power window 312 that provides the power to the plasma processing chamber 304 to create a plasma 314 in the plasma processing chamber 304. The TCP coil (upper power source) 310 may be configured to produce a uniform diffusion profile within the plasma processing chamber 304. For example, the TCP coil 310 may be configured to generate a toroidal power distribution in the plasma 314. The power window 312 is provided to separate the TCP coil 310 from the plasma processing chamber 304 while allowing energy to pass from the TCP coil 310 to the plasma processing chamber 304. A wafer bias voltage power supply 316 tuned by a match network 318 provides power to an electrode 320 to set the bias voltage on the silicon substrate 204, which is supported by the electrode 320, so that the electrode 320 in this embodiment is also a substrate support. A pulse controller 352 causes the bias voltage to be pulsed. The pulse controller 352 may be between the match network 318 and the substrate support, or between the bias voltage power supply 316 and the match network 318, or between the controller 324 and the bias voltage power supply 316, or in some other configuration to cause the bias voltage to be pulsed. A controller 324 sets points for the plasma power supply 306 and the wafer bias voltage supply 316.

The plasma power supply 306 and the wafer bias voltage power supply 316 may be configured to operate at specific radio frequencies such as, for example, 13.56 MHz, 27 MHz, 2 MHz, 400 kHz, or combinations thereof. Plasma power supply 306 and wafer bias power supply 316 may be appropriately sized to supply a range of powers in order to achieve desired process performance. For example, in one embodiment of the present invention, the plasma power supply 306 may supply the power in a range of 300 to 10000 Watts, and the wafer bias voltage power supply 316 may supply a bias voltage in a range of 10 to 2000 V. In addition, the TCP coil 310 and/or the electrode 320 may be comprised of two or more sub-coils or sub-electrodes, which may be powered by a single power supply or powered by multiple power supplies.

As shown in FIG. 3, the plasma processing system 300 further includes a gas source/gas supply mechanism 330. The gas source includes an oxide etch gas source 332, a strip gas source 334, and a residue clean gas sources 336. The gas sources 332, 334, and 336 are in fluid connection with the plasma processing chamber 304 through a gas inlet 340. The gas inlet may be located in any advantageous location in the plasma processing chamber 304, and may take any form for injecting gas. Preferably, however, the gas inlet may be configured to produce a “tunable” gas injection profile, which allows independent adjustment of the respective flow of the gases to multiple zones in the plasma processing chamber 304. The process gases and byproducts are removed from the plasma processing chamber 304 via a pressure control valve 342, which is a pressure regulator, and a pump 344, which also serves to maintain a particular pressure within the plasma processing chamber 304 and also provides a gas outlet. The gas source/gas supply mechanism 330 is controlled by the controller 324. A Kiyo system by Lam Research Corporation may be used to practice an embodiment of the invention.

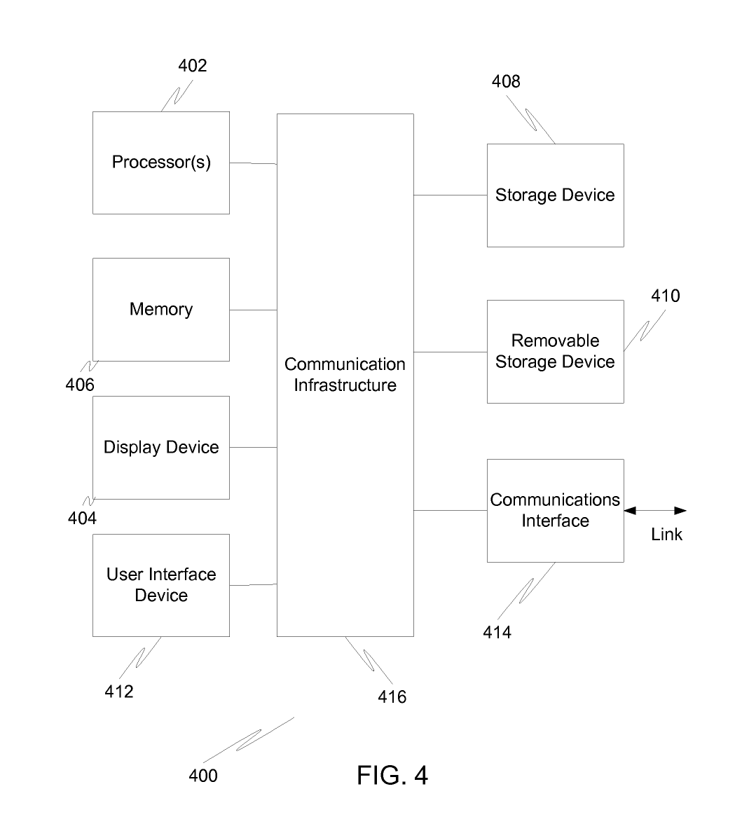

FIG. 4 is a high level block diagram showing a computer system 400, which is suitable for implementing a controller 324 used in embodiments of the present invention. The computer system may have many physical forms ranging from an integrated circuit, a printed circuit board, and a small handheld device up to a huge super computer. The computer system 400 includes one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and a communication interface 414 (e.g., wireless network interface). The communication interface 414 allows software and data to be transferred between the computer system 400 and external devices via a link. The system may also include a communications infrastructure 416 (e.g., a communications bus, cross-over bar, or network) to which the aforementioned devices/modules are connected.

Information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network, or might output information to the network in the course of performing the above-described method steps. Furthermore, method embodiments of the present invention may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

The oxide etch layer is selectively etched with respect to the patterned organic mask and the metal containing hardmask or etch stop (step 108). In an embodiment, the oxide etch comprises a plurality of cycles where each cycle comprises a selective mask deposition phase and a selective etch layer etch phase.

An example of a recipe for providing a selective mask deposition phase provides a chamber pressure of 3 mTorr. A deposition gas of 100 sccm Ar, 50 sccm H₂, and 15 sccm C₄F₈ is flowed into the plasma processing chamber 304. 400 watts of RF at 13.56 MHz is provided by the TCP coil 310 to form the deposition gas into a plasma 314. No deposition bias is provided by the wafer bias power supply 316, since the duty cycle is off during the selective mask deposition phase to provide a net deposition. In this example, since the deposition gas is the same recipe as the etch gas, the flow of the deposition gas does not need to be stopped.

An example of a recipe for providing an etch provides a chamber pressure of 3 mTorr. An etch gas of 100 sccm Ar, 50 sccm H₂, and 15 sccm C₄F₈ is flowed into the plasma processing chamber 304. 400 watts of RF at 13.56 MHz is provided by the TCP coil 310 to form the etch gas into a plasma 314. An etch bias of 500 volts, generated by providing an RF at 13.56 MHz, is provided by turning on the bias power from the wafer bias power supply 316 during a pulsed bias, where the etching phase is during the on part of the duty cycle. In this example, since the etch gas is the same recipe as the deposition gas, the flow of the etch gas does not need to be stopped. There may be some deposition during this phase, but during this phase there is no net deposition. More preferably, there is a net removal of the deposition.

If the etch phase does not remove all of the deposition, so that the deposition prevents any of the organic mask and hardmask from being etched, then the resulting etch may have an infinite selectivity for etching the etch layer with respect to both the organic mask and hardmask.

FIG. 2B is a schematic cross-sectional view of the stack 200 after the oxide etch layer 212 has been etched to form features 232 in the oxide etch layer 212. In this example, metal residue from the metal containing hardmask 224 and/or the metal containing etch stop layer 208 is etched and redeposited to form sidewall deposits 236 on sides of the stacks. In this example, the metal residue contains Ti or is Ti.

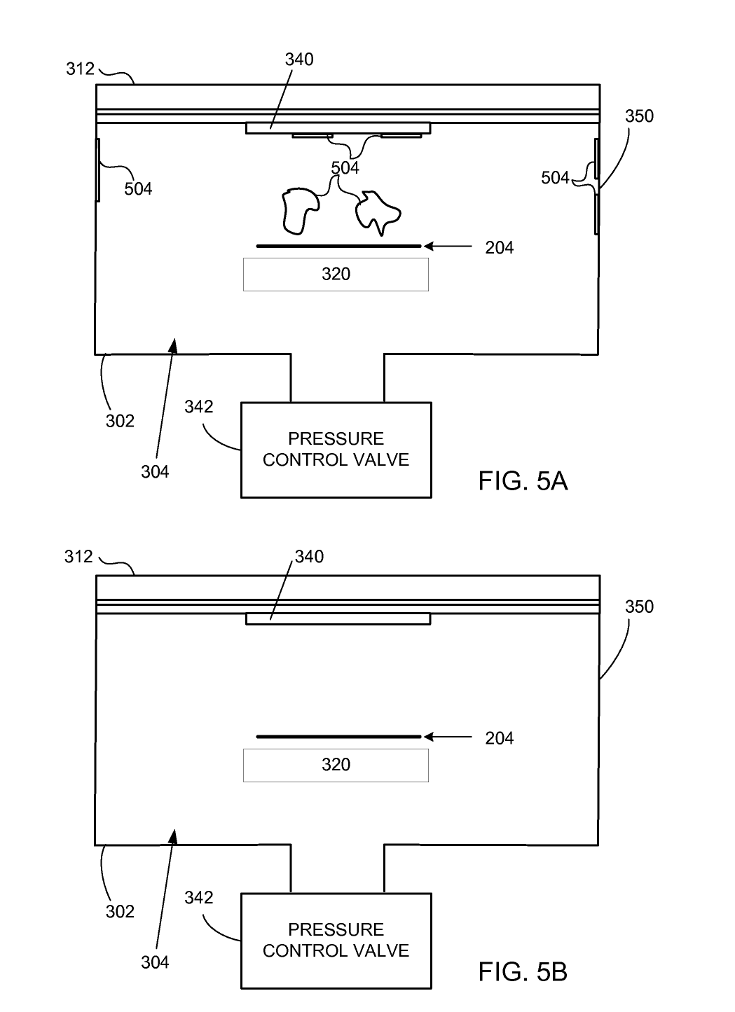

FIG. 5A is an enlarged view of the plasma reactor 302, which schematically illustrates metal residue 504 from the metal containing hardmask 224 and/or the metal containing etch stop layer 208 that is etched and redeposited on the chamber wall 350 and other parts of the chamber.

The organic mask is stripped (step 112). An example of a recipe for stripping the organic mask provides a pressure of 5 mTorr. A strip gas of 100 sccm Cl₂ and 100 sccm O₂ is flowed into the plasma processing chamber 304. A bias of 50 volts is provided. TCP power of 1,000 watts is provided. The process is maintained for 60 seconds. FIG. 2C is a schematic cross-sectional view of the stack 200 after the organic mask is stripped. The stripping does not remove the sidewall deposits 236 (FIG. 2C) or the metal residue 504 (FIG. 5A).

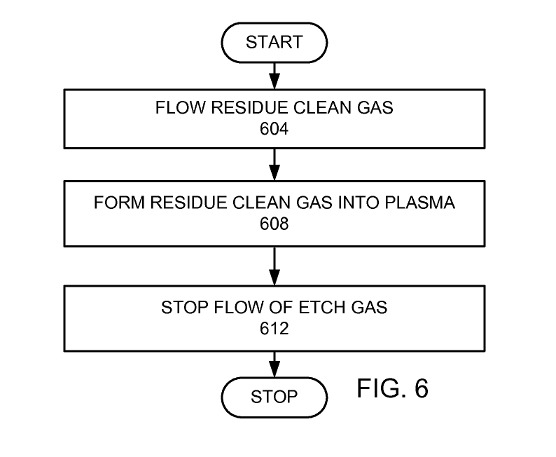

The metal residue 504 is cleaned (step 116). FIG. 6 is a more detailed flow chart of the step of cleaning the metal residue 504. A residue clean gas is flowed from the residue clean gas source 336 into the plasma processing chamber 304 (step 604). Preferably, the residue clean gas comprises BCl₃. More preferably, the residue clean gas further comprises Cl₂. The residue clean gas is formed into a plasma 314 (step 608). The flow of the residue clean gas is stopped (step 612).

An example of a recipe for cleaning, provides a chamber pressure of 10 mTorr. A residue clean gas of 200 sccm BCl₃ and 30 sccm Cl₂ is flowed from the clean gas source 336 into the plasma processing chamber 304 (step 604). The residue clean gas is formed into a plasma 314 by providing 500 watts RF at 13.56 MHz (step 608). The process is maintained for 5 seconds before the flow of the residue clean gas is stopped (step 612). FIG. 2D is a schematic view of the stack 200 after the residue clean has been completed. The metal containing sidewall deposits have been removed. FIG. 5B is an enlarged view of the plasma reactor 302 after the residue clean, which schematically illustrates that metal residue has been cleaned from the chamber wall 350 and other parts of the plasma processing chamber 304.

Additional processing steps may be performed while the substrate remains in the plasma processing chamber 304. The substrate is then removed from the plasma processing chamber 304 (step 120) after the metal residue is cleaned and after any additional processing steps.

In another embodiment, a residue clean recipe may provide a pressure of 5 mTorr. The clean gas comprises 100 sccm BCl₃ and 50 sccm Cl₂. 200 watts RF is provided at 13.56 MHz. The process is maintained for 5 seconds.

If the metal residue is not removed from the stack, the metal residue can block pattern transfer and lead to defectivity issues in subsequent processing. In addition, the metal residues can also result in corrosion or condensation defects when exposed to atmosphere. If the metal residue is not removed from the chamber walls 350, the plasma processing chamber 304 is subject to process drift and defectivity. Therefore, cleaning the metal residue from the stack 200 and the chamber walls 350 reduce device defects and plasma processing chamber drift. These embodiments preferably allow cleaning with minimal or no etching of the metal containing hardmask 224 or etch stop layer 208. In addition, these embodiments allow for the simultaneous cleaning of metal deposits on the stack 200 and on the chamber wall 350 with minimal or no etching of the metal containing hardmask 224 or etch stop layer 208.

Although in the previous embodiment, both the hardmask and etch stop are metal containing, in other embodiments only the hardmask is metal containing and the etch stop is not metal containing, or the etch stop is metal containing and the hardmask is not metal containing. In various embodiments, the metal containing hardmask or etch stop may be TiN, Ta, Ti, Ta₂O₃, Ti₂O₃, Al₂O₃, or Al. If the hardmask or etch stop is not metal containing, it may be SiN or another nitride. Preferably, the etch layer is a silicon oxide based layer.

Preferably, the residue clean gas comprises BCl₃. More preferably, the residue clean gas comprises BCl₃ and Cl₂. Preferably, the flow of BCl₃ is greater than the flow of Cl₂. More preferably, the flow rate of BCl₃ is at least twice the flow rate of Cl₂. Most preferably, the flow rate of BCl₃ is at least five times the flow rate of Cl₂. The higher concentration of BCl₃ with respect to Cl₂ has been found to increase residue removal, while reducing etching of the metal containing hardmask or etch stop. The residue clean gas is fluorocarbon free.

Preferably, the residue cleaning has a self bias of less than 20 volts. More preferably, the residue cleaning has a self bias of 0 volts, so that the RF bias is zero. The low bias allows for removing the metal residue, while minimizing etching.

In one embodiment the metal containing hardmask 224 is removed before removing the stack 200 from the plasma processing chamber 304. In another embodiment, the metal containing hardmask 224 is removed after removing the substrate 204 from the plasma processing chamber 304. In other embodiments, additional steps may be provided. For example, the stack 200 is removed from the plasma processing chamber 304 before the metal hardmask 224 is removed. A second mask may then be formed over the hardmask 224 for a double patterning process. The stack 200 may then be placed in the plasma processing chamber 304 for additional etching. In another embodiment, additional etch steps may be performed before the stack 200 is removed from the plasma processing chamber 304. For example, a subsequent etch may use the etch layer as a mask for etching the metal containing etch stop layer.

While this invention has been described in terms of several preferred embodiments, there are alterations, modifications, permutations, and various substitute equivalents, which fall within the scope of this invention. It should also be noted that there are many alternative ways of implementing the methods and apparatuses of the present invention. It is therefore intended that the following appended claims be interpreted as including all such alterations, modifications, permutations, and various substitute equivalents as fall within the true spirit and scope of the present invention.

What is claimed is:

1. A method for forming devices in an oxide layer over a substrate, wherein a metal containing layer forms at least either an etch stop layer below the oxide layer or a patterned mask above the oxide layer, wherein a patterned organic mask is above the oxide layer, comprising:
placing the substrate in a plasma processing chamber;
etching the oxide layer through the patterned organic mask, wherein metal residue from the metal containing layer forms metal residue on sidewalls of the oxide layer;
stripping the patterned organic mask;
cleaning the metal residue, comprising:
providing a cleaning gas comprising BCl₃; and
forming a plasma from the cleaning gas; and
removing the substrate from the plasma processing chamber.

2. The method, as recited in claim 1, wherein the cleaning gas further comprises Cl₂.

3. The method, as recited in claim 2, wherein the cleaning gas has a flow ratio of BCl₃ to Cl₂ that is greater than 1:1.

4. The method, as recited in claim 3, wherein the cleaning gas has a flow ratio of BCl₃ to Cl₂ that is greater than 2:1.

5. The method, as recited in claim 3, wherein the cleaning gas has a flow ratio of BCl₃ to Cl₂ that is greater than 5:1.

6. The method, as recited in claim 3, wherein the cleaning the metal residue has an RF bias of zero.

7. The method, as recited in claim 3, wherein the cleaning the metal residue has a bias of less than 20 volts.

8. The method, as recited in claim 7, wherein during the cleaning the metal residue, the oxide layer is not etched.

9. The method, as recited in claim 2, wherein the metal containing layer comprises a metal that forms a volatile chloride.

10. The method, as recited in claim 2, wherein the metal containing layer comprises at least one of Al, Ti, or Ta.

11. The method, as recited in claim 10, wherein the etching the oxide layer, comprises:
providing an oxide etch gas, comprising a fluorocarbon, wherein the cleaning gas is fluorocarbon free; and
forming a plasma from the oxide etch gas.

12. The method, as recited in claim 2, wherein the etching the oxide layer, comprises:
providing an oxide etch gas, comprising a fluorocarbon, wherein the cleaning gas is fluorocarbon free; and
forming a plasma from the oxide etch gas.

13. The method, as recited in claim 1, wherein during the cleaning the metal residue, the oxide layer is not etched.

14. The method, as recited in claim 1, wherein etching the oxide layer further forms metal residues on walls of the plasma processing chamber, wherein the cleaning the metal residue cleans metal residues on walls of the plasma processing chamber.

15. The method, as recited in claim 1, further comprising removing the metal containing hardmask.

16. A method for forming devices in an oxide layer over a substrate, wherein a metal containing layer forms at least either an etch stop layer below the oxide layer or a patterned mask above the oxide layer, wherein a patterned organic mask is above the oxide layer, comprising:
placing the substrate in a plasma processing chamber;
etching the oxide layer through the patterned organic mask, wherein metal residue from the metal containing layer forms metal residue on sidewalls of the oxide layer;
stripping the patterned organic mask;
cleaning the metal residue, comprising:
providing a cleaning gas comprising BCl₃ and Cl₂, wherein the cleaning gas has a flow ratio of BCl₃ to Cl₂ that is greater than 2:1; and
forming a plasma from the cleaning gas; and
removing the substrate from the plasma processing chamber.

17. The method, as recited in claim 16, wherein during the cleaning the metal residue, the oxide layer is not etched.

18. The method, as recited in claim 16, wherein etching the oxide layer further forms metal residues on walls of the plasma processing chamber, wherein the cleaning the metal residue cleans metal residues on walls of the plasma processing chamber.
